(19) United States
(12) Patent Application Publication
(10) Pub. No.: US 2009/0108858 A1
(43) Pub. Date: Apr. 30, 2009

(54) METHODS AND SYSTEMS FOR CALIBRATING RC CIRCUITS

(75) Inventors: Shiau-Wen Kao, Hsinchu City (TW); Ming-Ching Kuo, Hsinchu City (TW); Chih-Hung Chen, Kaohsiung City (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Industrial Technology Research Institute

(21) Appl. No.: 12/195,585

(22) Filed: Aug. 21, 2008

Related U.S. Application Data
(60) Provisional application No. 60/960,989, filed on Oct. 24, 2007.

(51) Int. Cl. H01G 7/00; G01R 23/175; G01R 31/28

(52) U.S. Cl. 324/754; 29/25.41; 29/593; 324/76.54

(57) ABSTRACT

A calibration apparatus includes an RC integrator circuit. The calibration apparatus further includes a bandwidth setting controller to provide a bandwidth setting code indicating a reference bandwidth value for calibration of the RC integrator circuit and a capacitance code generator, coupled to the RC integrator circuit, to generate a capacitance code to adjust a capacitance of the RC integrator circuit using the bandwidth setting code and a current capacitance value of the RC integrator circuit.

### RELATED APPLICATIONS

This application claims priority from U.S. Provisional Patent Application No. 60/960,989 filed Oct. 24, 2007, the contents of which are hereby incorporated by reference.

### TECHNICAL FIELD

Systems and methods disclosed herein relate to the field of electronic circuits and, more specifically, to systems and methods that calibrate resistor-capacitor (RC) circuits.

### DESCRIPTION OF THE RELATED ART

RC filters are commonly used in integrated circuits to control the frequency of poles and zeros. However, due to manufacturing defects and variations in operating conditions, there is typically a 25% to 50% variation in resistance and capacitance values of the RC filters. One way of accounting for these variations is to use a variable capacitance array, which adjusts the value of the capacitance to maintain the value of the RC time constant and control the frequency of poles and zeros.

FIG. 1 illustrates a conventional RC calibration circuit 100. The RC calibration circuit 100 includes a resistor 110 connected in parallel with a capacitor 112, between a node N and ground. Current source 114 provides current I_{N} into node N causing a potential drop V_{N} across resistor 110 and capacitor 112. Typically, capacitor 112 is implemented as a variable capacitor that functions as a digital-to-analog converter (DAC). Capacitor 112 receives a digital control word (DCW) from digital logic 116, converts the DCW to an analog value, and sets its capacitance based on the analog value. Digital logic 116 is further connected to a switch 118 and a digital counter 120, which is configured to receive a clock signal CLK from a clock source (not shown). Additionally, RC calibration circuit 100 includes an analog comparator 122, which compares V_{N} with a reference voltage V_{REF} and outputs a comparison signal to digital counter 120.

Prior to operation, switch 118 is closed and V_{N} is set to ground. When operation begins at time t_{zero}, digital logic 116 sends a switch pulse to open switch 118, digital counter 120 begins counting the rising edges of clock signal CLK, and V_{N} starts increasing exponentially according to the equation:

V_{N}=Vₘₐₓ(1−e^{t/τ}),

where Vₘₐₓ represents the maximum voltage across capacitor 112, t represents the elapsed time and τ represents the RC time constant.

As soon as V_{N} exceeds V_{REF}, comparator 122 sends a comparison signal to digital counter 120, causing digital counter 120 to stop counting and record the current count at time t_{cmp}. At time t_{cmp}, V_{N} is approximately equal to V_{REF} and t is equal to t_{cmp}-t_{zero}. Once the count is recorded, the falling edge of the switch pulse causes switch 118 to close. When switch 118 closes, counter 120 is reset to zero and V_{N} discharges back to ground.

Digital logic 116 captures the number of clock pulses counted by counter 120 and solves the above equation to determine the value of τ. The calculated value of τ is compared to a predetermined time constant and, depending on the comparison, digital logic 116 sends a new DCW to increase or decrease the capacitance of capacitor 112 by one-step. However, if the difference between the value of τ and the predetermined time constant is not sufficiently adjusted by a one-step increase or decrease, the process is repeated at a second clock period, for an additional one-step change. Under such circumstances, a comparison is performed for every clock period until the desired value of τ is reached.

One of the problems with calibration circuit 100 is that multiple comparisons lead to increased power consumption. Further, if a comparison is made every clock period, comparator 122 and counter 120 must be reset each clock period and digital logic 116 must solve an exponential equation each clock period. These steps may cause delays and inaccuracies. In addition, calibration circuit 100 is limited to calibrating the RC circuit at a fixed frequency.

### SUMMARY

Consistent with embodiments of the invention, a calibration apparatus is provided. The apparatus comprises an RC integrator circuit;, a bandwidth setting controller to provide a bandwidth setting code indicating a reference bandwidth value for calibration of the RC integrator circuit; and a capacitance code generator, coupled to the RC integrator circuit, to generate a capacitance code to adjust a capacitance of the RC integrator circuit using the bandwidth setting code and a current capacitance value of the RC integrator circuit.

Also consistent with embodiments of the present invention, there is provided an apparatus comprising an RC integrator circuit; a bandwidth setting controller to provide a bandwidth setting code indicating a reference bandwidth value for calibration of the RC integrator circuit; and a capacitance code generator, coupled to provide feedback to the RC integrator circuit, to adjust capacitance of the RC integrator circuit using the bandwidth setting code and a current capacitance value of the RC integrator circuit.

Further consistent with embodiments of the present invention, a calibration apparatus is provided. The apparatus comprises an RC integrator circuit including an output terminal; a control clock generator, to generate a plurality of control clocks; a counter, coupled to the control clock generator to count clock pulses of at least one of the plurality of control clocks; a comparator, coupled to the output terminal, to compare a reference voltage with a voltage at the output terminal and to generate a trigger event to trigger the counter to stop counting; a digital controller to receive the counted clock pulses and to generate a bandwidth setting code; and a capacitance code generator, coupled to the RC integrator circuit, to generate a capacitance code to adjust a capacitance of the RC integrator circuit using a current capacitance value of the RC integrator circuit and the bandwidth setting code.

Also consistent with embodiments of the present invention, a method for calibrating an RC integrator circuit is provided. The method comprises receiving a bandwidth setting code indicating a reference bandwidth value for calibration of the RC integrator circuit; calculating a current capacitance value of the RC integrator circuit; and generating a capacitance code to adjust the current capacitance value of the RC integrator using the bandwidth setting code and the current capacitance value of the RC integrator circuit.

Additionally consistent with embodiments of the present invention, a method for calibrating an RC integrator circuit is provided. The method comprises generating a plurality of control clocks; counting clock pulses of at least one of the plurality of control clocks; comparing a reference voltage with a voltage at an output terminal of an RC integrator circuit; causing the counter to stop counting; calculating a difference between a bandwidth setting code and a number of the counted clock pulses; and adjusting the capacitance of the RC integrator circuit based on the difference.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate various embodiments. In the drawings:

FIG. 1 is a schematic diagram of a conventional RC calibration circuit;

FIG. 2 is a schematic diagram illustrating a calibration apparatus including an RC circuit, consistent with an embodiment of the invention;

FIG. 3 is a timing diagram illustrating the operation of an RC calibration circuit, consistent with an embodiment of the invention;

FIG. 4 shows a flow diagram of an exemplary method for calibrating an RC integrator, in accordance with an embodiment of the invention;

FIG. 5 is a schematic diagram illustrating an integrator calibration circuit, consistent with an embodiment of the invention; and

FIG. 6 is a schematic diagram illustrating a calibration circuit, consistent with an embodiment of the invention.

### DESCRIPTION OF THE EMBODIMENTS

In the following description, for purposes of explanation and not limitation, specific techniques and embodiments are set forth, such as particular sequences of steps, interfaces and configurations, in order to provide a thorough understanding of the techniques presented herein. While the techniques and embodiments will primarily be described in context with the accompanying drawings, those skilled in the art will further appreciate that the techniques and embodiments can also be practiced in other circuit types.

Reference will now be made in detail to the exemplary embodiments of the invention, examples of which are illustrated in the accompanying drawings. Wherever possible, the same reference numbers will be used throughout the drawings to refer to the same or like parts.

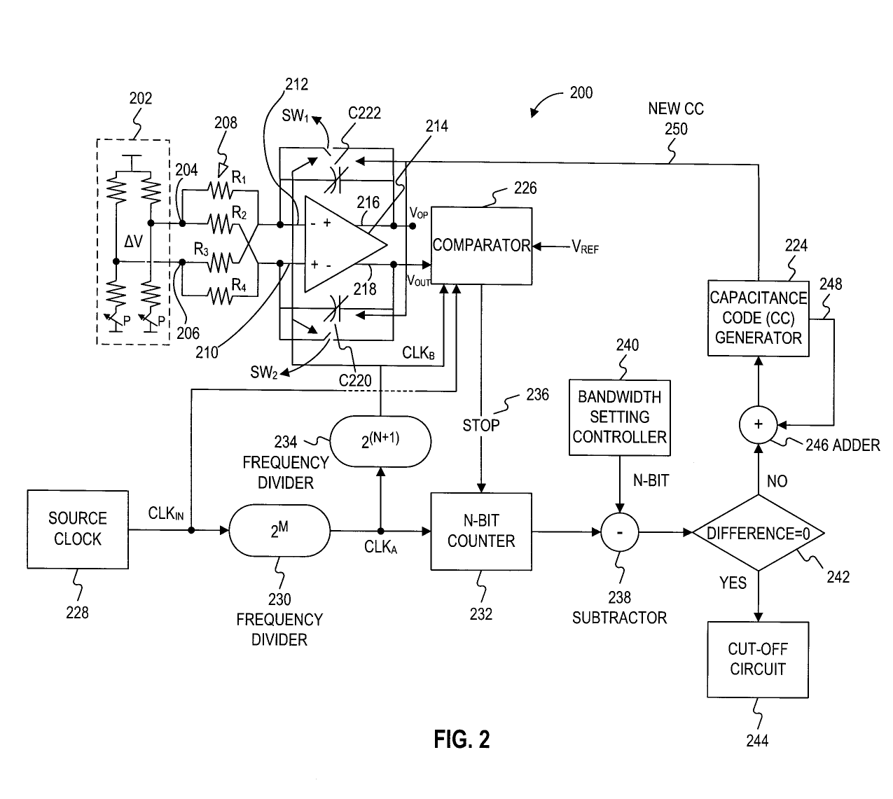

FIG. 2 illustrates a calibration apparatus 200 for calibrating an RC circuit, which may overcome one or more of the aforementioned deficiencies of conventional calibration circuits. With reference to FIG. 2, a power source block 202 is configured to provide a voltage ΔV on terminals 204 and 206 to an arrangement of resistors 208 including resistors R₁-R₄. As a result, a voltage is provided at input terminals 210 and 212 of an operational amplifier (op-amp) 214. As shown in FIG. 2, op-amp 214 includes “+” and “−” inputs 210 and 212, respectively, and “+” and “−” outputs 216 and 218, respectively. A capacitor C220 is coupled between input 210 and output 218 of op-amp 214. A capacitor C222 is coupled between input 212 and output 216 of op-amp 214. As shown in FIG. 2, resistors R₁-R₄ coupled to capacitors C220 and C222 form an RC circuit. Although four resistors and two capacitors are shown in FIG. 2, one skilled in the art will appreciate that lesser or greater number of resistors and capacitors may be associated with different types of calibration circuits. Further, the relevant capacitance or resistance may be measured as the equivalent resistance of all of the resistors and the equivalent capacitance of the plurality of capacitors. For example, in the present embodiment, resistors R₁ and R₂ may be replaced by a single resistor of the resistance value (R₁R₂)/(R₂-R₁).

Capacitors C220 and C222 may be implemented as capacitor arrays that function as digital-to-analog converters (DACs). For example, each of capacitors C220 and C222 may be implemented as an array of binary-weighted capacitors or as fractional-weighted capacitors. Alternatively, DACs may be coupled to capacitors C220 and C222 to set the capacitance value of the capacitors.

The capacitance value of capacitors C220 and C222 is set based on a digital capacitance code (CC) generated by a capacitance code generator 224. Capacitors C220 and C222 receive a CC and convert the CC to analog capacitance values. Further, a switch SW₁ is coupled in parallel to C222 and a switch SW₂ is coupled in parallel to capacitor C220. When switches SW₁ and SW₂ are closed, two voltages (Vₒₚ and Vₒᵤₜ) at output terminals 216 and 218 of op-amp 214, may be at a common mode point of op-amp 214. Opening switches SW₁ and SW₂ may cause capacitors C222 and C220 to discharge, causing Vₒₚ to be charged to a maximum positive voltage output of op-amp 214 and causing Vₒᵤₜ to be charged to a maximum negative voltage output of op-amp 214. The Vₒᵤₜ terminal 218 of op-amp 214 is coupled to a comparator 226, which may be implemented using a digital or analog comparator. Comparator 226 is further provided with a reference voltage V_{ref} and performs a comparison between Vₒᵤₜ and V_{ref}. Although Vₒₚ and Vₒᵤₜ at output terminals 216 and 218 may be at a common mode point of op-amp 214 and Vₒᵤₜ and V_{ref} may be represented by single-ended signals, one skilled in the art will appreciate that calibration apparatus 200 may be implemented with differential signals. For example, op-amp 214 may amplify a difference between an input voltage across input terminals 210 and 212 and provide the amplified difference as a differential signal Vₒᵤₜ. Similarly, V_{ref} may be provided as a differential signal.

A source clock 228 provides clock pulses CLKᵢₙ to a frequency divider 230 and comparator 226. Frequency divider 230 generates counter clock pulses CLK_{A} by reducing the frequency of CLKᵢₙ by 2^{M}, where M is an integer indicating the number of comparisons performed by comparator 226 in one clock period of CLK_{A}. CLK_{A} may be input into an N-bit counter 232, where N is an integer indicating the number of bits used to calculate the digital capacitance of capacitors C220 and C222. N-bit counter 232 counts the number of clock pulses of CLK_{A} being inputted in N-bit counter 232. CLK_{A} may also be input into a frequency divider 234. Frequency divider 234 generates clock pulses CLK_{B} by reducing the frequency of CLK_{A} by ₂(N+1), and provides CLK_{B} to comparator 226 and to switches SW₁ and SW₂.

As is described in further detail below, when CLK_{B} is high, switches SW₁ and SW₂ may be closed and Vₒₚ and Vₒᵤₜ may be almost at the common mode point of op-amp 214. However, when CLK_{B} becomes low, switches SW₁ and SW₂ may be pulsed open by CLK_{B} and N-bit counter 232 may start counting clock pulses of CLK_{A}. Opening switches SW₁ and SW₂ may cause capacitors C220 and C222 to discharge, thus causing Vₒᵤₜ to be charged to the maximum negative voltage output of op-amp 214. The discharging behavior of C220 and C222 depends on a slew rate of op-amp 214, which is based on the respective capacitances of capacitors C220 and C222 and a saturation current of op-amp 214. The slew rate of op-amp 214 causes the discharge behavior to be more linear and precise than the exponential discharge behavior of conventional RC calibration apparatus. Comparator 226 compares Vₒᵤₜ with V_{ref}, while being clocked by CLK_{B} and CLKᵢₙ and the number of comparisons performed between Vₒᵤₜ and V_{ref}, during one clock period of CLK_{A}, may be controlled by the frequency of CLKᵢₙ.

When Vₒᵤₜ is less than V_{ref} and CLK_{B} is low, comparator 226 generates a trigger event to trigger N-bit counter 232 to stop counting (236). The number of counted clock pulses is captured by a subtractor 238. Subtractor 238 is also connected to a bandwidth setting controller 240, which inputs an N-bit bandwidth code into subtractor 238. The N-bit bandwidth code serves as a reference value representing a calibrated bandwidth value of the RC circuit. Each time the RC circuit is calibrated, the bandwidth setting controller 240 provides the N-bit bandwidth code, representing a reference value for the calibration. Accordingly, the RC circuit may be calibrated at different bandwidths.

Subtractor 238 calculates the difference between the bandwidth setting code and the counted clock pulses. If a difference 242 is zero, a cut-off circuit 244 removes power from the power consuming analog circuits to prevent static power consumption and stops clocking the digital circuits to prevent dynamic power consumption and clock noise. The power may be removed when the difference is zero because a difference of zero indicates that the RC time constant is operating at the predetermined time constant and, therefore, there is no need to calibrate the circuit. However, when the difference is not zero, subtractor 238 sends the difference to an adder 246. Adder 246 is connected to capacitance code generator 224, which inputs a current value CC 248 into adder 246. Current CC 248 reflects the current capacitance values of capacitors C220 and C222.

To calibrate the RC circuit, capacitance code generator 224 generates a new value CC 250 based on the addition of the difference, calculated by the subtractor, and the current CC 248. CC 250 is provided as feedback to capacitors C220 and C222 to adjust the capacitance values of the RC circuit. The capacitance values are adjustable so that the RC time constant may be calibrated to the predetermined RC time constant.

This process may be repeated to calibrate the RC circuit at a different bandwidth or the RC circuit may be calibrated at different temperatures. Calibration apparatus 200 controls the time constant for an RC circuit based on the following relationship:

RC α T_{CLKA}N_{BWC},

where R represents the equivalent resistance of all the resistors in the RC circuit, C represents the equivalent capacitance of the RC circuit, T_{CLKA} represents a clock period of the counter clock pulses, and N_{BWC} represents an N-bit bandwidth code which may be set to arbitrary codes for corresponding RC time constants. The N-bit bandwidth code is inputted by bandwidth setting controller 240. Thus, the time constant (RC) based on the above equation is represented by a linear relationship and provides a precise and accurate time constant during the calibration.

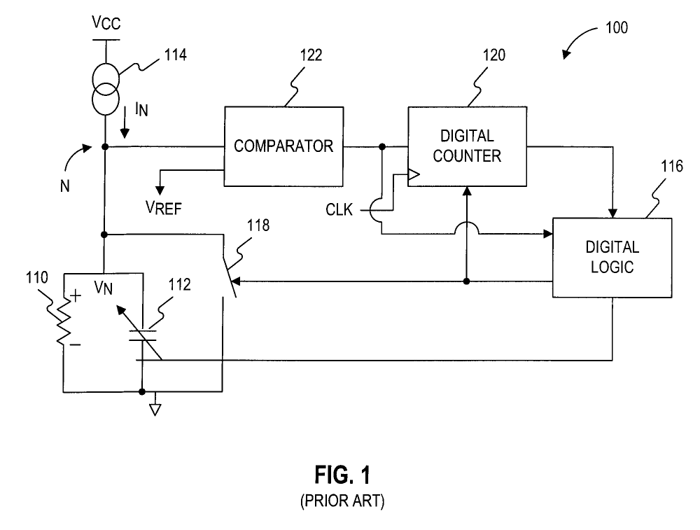

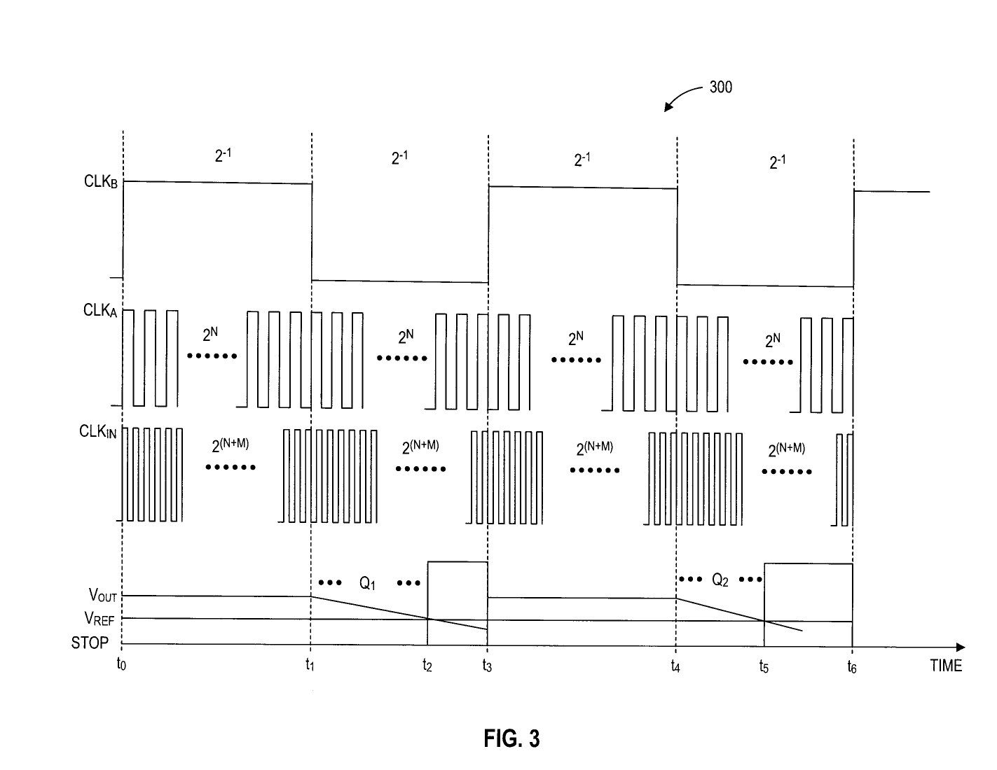

Referring now to FIG. 3, a timing diagram 300 is provided illustrating the operation of an RC calibration circuit, consistent with an embodiment of the invention. For example, FIG. 3 is a timing diagram of calibration apparatus 200. As illustrated in FIG. 3, CLKᵢₙ has a highest frequency of 2^{(N+M)}, CLK_{A} has a lower frequency of 2^{(N)}, and CLK_{B} has a lowest frequency of 2⁽⁻¹⁾. At time to, CLK_{B}, CLK_{A}, and CLKᵢₙ are high, while switches SW₁ and SW₂ are closed. At time t₁, CLK_{B} is set to low, switches SW₁ and SW₂ are pulsed open and Vₒᵤₜ starts decreasing. N-bit counter 232 starts counting CLK_{A} pulses and counts the pulses for a period of Q₁. At time t₂, comparator 226 generates a trigger event to trigger N-bit counter 232 to stop counting and V_{ref} is greater than Vₒᵤₜ. The remaining calibration is performed as described with respect to FIG. 1 above. Further, at time t₃, switches SW₁ and SW₂ are closed and CLK_{B} is set high. CLK_{B} is set low again at time t₄ and the above cycle may be repeated from time t₄ to t₆.

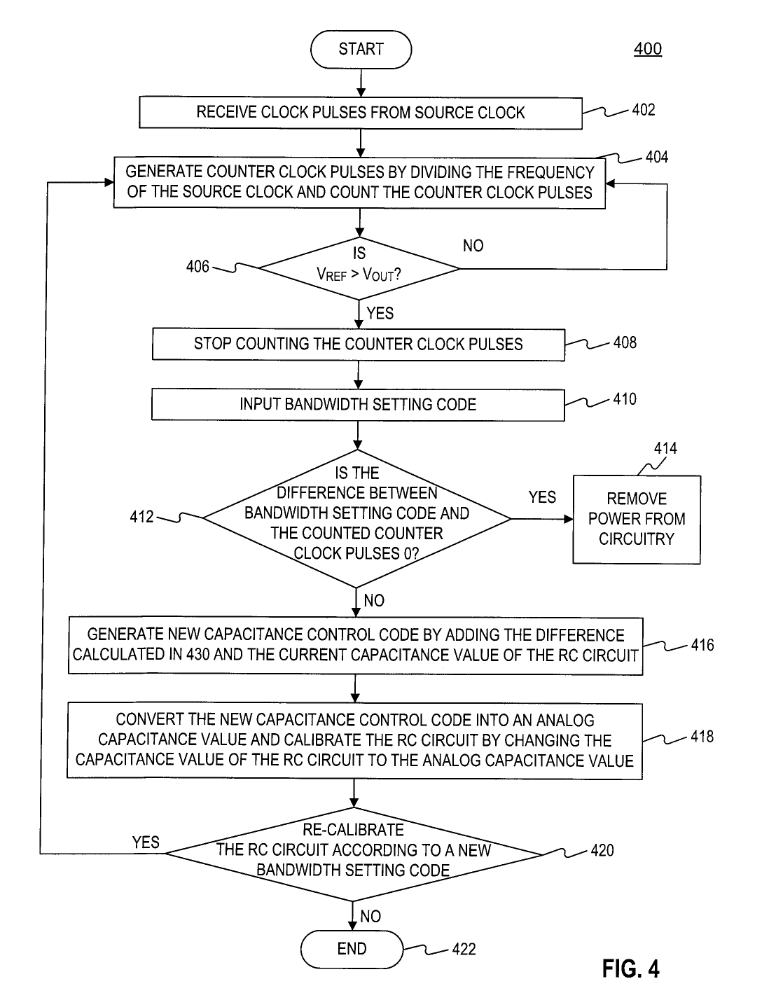

FIG. 4 shows a flow diagram of a method 400 for calibrating an RC circuit in accordance with an embodiment of the invention. Method 400 represents operation of calibration apparatus 200. The method starts in step 402 where the calibration apparatus receives clock pulses from a source clock. In step 404, counter clock pulses are generated by dividing the frequency of the source clock and the counter clock pulses are counted when one or more capacitors in the RC start discharging. Next, in step 406, it is determined if V_{ref} is greater than Vₒᵤₜ. If V_{ref} is not greater than Vₒᵤₜ, the counter continues counting the counter clock pulses (step 404). If V_{ref} is determined to be greater than Vₒᵤₜ, the process moves to step 408. In step 408, the counter is triggered to stop counting.

In step 410, a bandwidth setting code reflecting the bandwidth at which the RC circuit is calibrated is inputted. In step 412, the difference between the bandwidth setting code and the number of counted clock pulses is determined. When the difference between the bandwidth setting code and the number of counted clock pulses is zero, power and clock are removed from the digital and analog circuitry in calibration apparatus 200 and calibration is stopped (step 414). However, when the difference is not zero, the method proceeds to step 416 at which a new capacitance code may is generated by adding the difference calculated in step 412 to the current capacitance value of the RC circuit. Next, in step 418, the new capacitance code is be converted into an analog capacitance value and the RC circuit is calibrated by setting the capacitance value of the RC circuit to the converted analog capacitance value. Next, in step 420 it may be determined to re-calibrate the RC circuit at a different bandwidth by returning to step 404. If the RC circuit is not to be re-calibrated, the calibration is completed and the method ends (step 422).

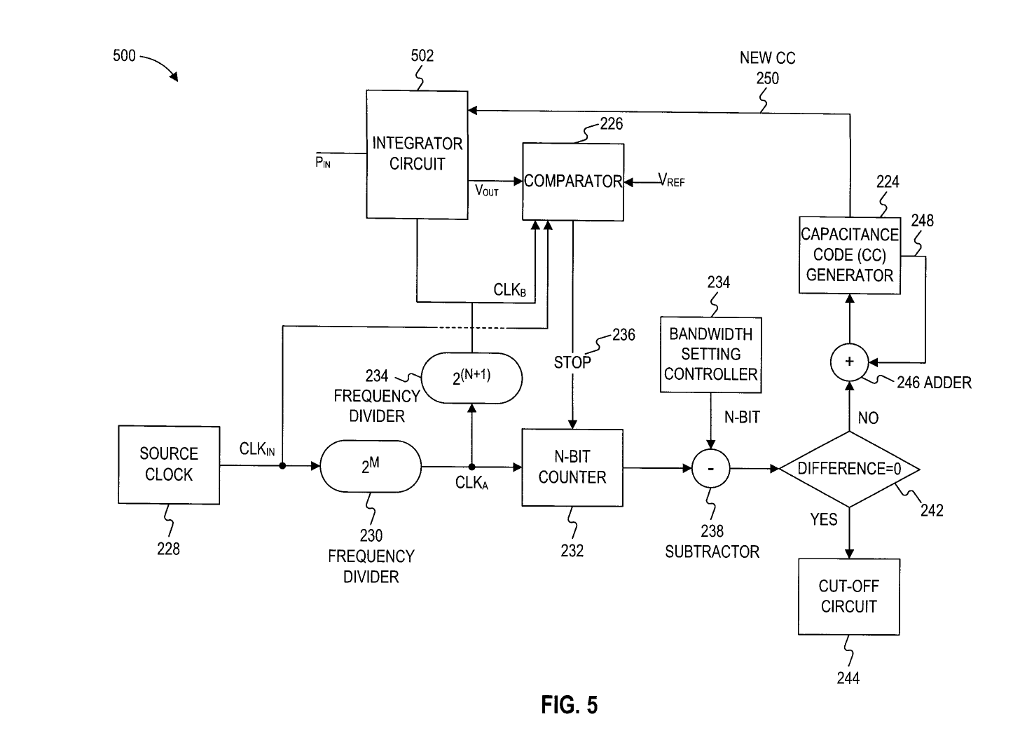

FIG. 5 illustrates an example of a calibration apparatus 500 that may be used to calibrate an integrator circuit 502. Integrator circuit 502 is calibrated by adjusting the capacitance of integrator circuit 502 based on a new CC 250 generated using capacitance code generator 224. The remaining circuitry operates similar to the circuitry in calibration apparatus 200 and the calibration is performed according to the steps described above, with respect to FIG. 2 or FIG. 4.

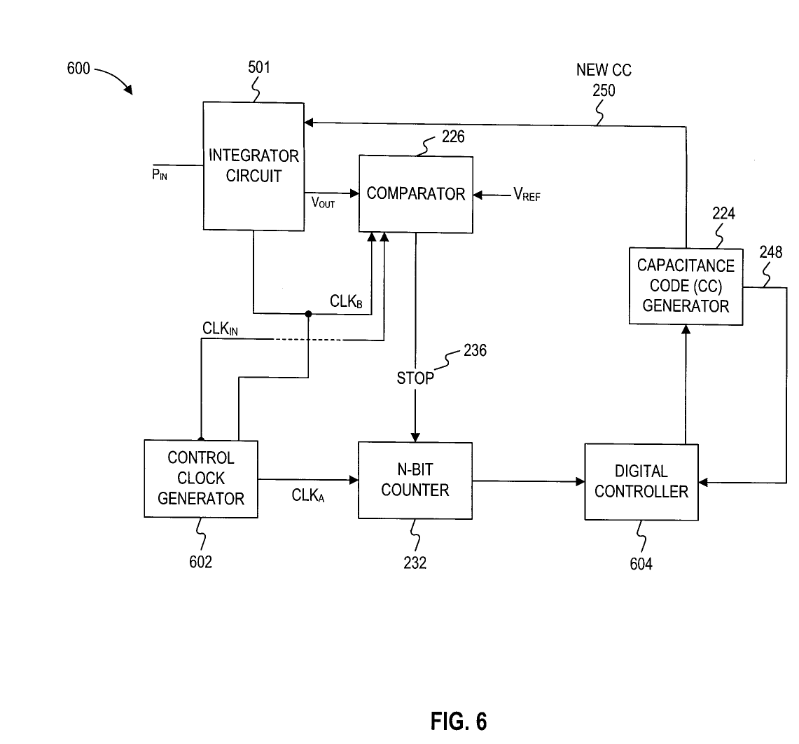

FIG. 6 illustrates an example of calibration apparatus 600 that may be used to calibrate integrator circuit 502. Integrator circuit 502 is calibrated by adjusting the capacitance of integrator circuit 502 based on a new CC 250 generated using capacitance code generator 224. The clocking operations of calibration apparatus 600 is controlled by a control clock generator 602. Control clock generator 602 generates CLKᵢₙ, CLK_{A}, and CLK_{B}, for clocking various components in calibration apparatus 600. Control clock generator 602 also includes a plurality of frequency dividers (not shown), similar to the ones shown in FIG. 2.

Calibration apparatus 600 controls part of the calibration using a digital controller 604. For example, when Vₒᵤₜ is less than V_{ref} and CLK_{B} is low, comparator 226 generates a trigger event to trigger N-bit counter 232 to stop counting 236, and the number of counted clock pulses is captured by digital controller 604. Digital controller 604 includes various digital components (not shown) including a subtractor circuit, an adder circuit, a bandwidth setting controller, and a cut-off circuit, similar to the corresponding features illustrated in FIG. 2, and performs the steps described above, with respect to FIG. 2 or FIG. 4. The remaining circuitry in calibration apparatus 600 operates in a manner similar to the circuitry in calibration apparatus 200 and the calibration is performed according to steps 402-422, described with reference to FIG. 4.

The foregoing description has been presented for purposes of illustration. It is not exhaustive and does not limit the invention to the precise forms or embodiments disclosed. Modifications and adaptations of the invention will be apparent to those skilled in the art from consideration of the specification and practice of the disclosed embodiments of the invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A calibration apparatus, comprising:
an RC integrator circuit;
a bandwidth setting controller to provide a bandwidth setting code indicating a reference bandwidth value for calibration of the RC integrator circuit;
a capacitance code generator, coupled to the RC integrator circuit, to generate a capacitance code to adjust a capacitance of the RC integrator circuit using the bandwidth setting code and a current capacitance value of the RC integrator circuit.

2. The calibration apparatus of claim 1, wherein the RC integrator circuit comprises a plurality of resistors and a plurality of variable capacitors, the capacitance of the RC integrator circuit being based on an equivalent capacitance of the plurality of variable capacitors at the time of the calibration.

3. The calibration apparatus of claim 2, wherein the capacitance of the RC integrator circuit is adjusted by changing the capacitance of at least one of the plurality of variable capacitors.

4. The calibration apparatus of claim 3, wherein at least one of the plurality of variable capacitors includes an array of binary-weighted capacitors functioning as a digital-to-analog converter (DAC), to set the capacitance of the at least one variable capacitor by converting the capacitance control code into an analog capacitance value.

5. The calibration apparatus of claim 1 further, comprising:
a control clock generator, to generate a plurality of control clocks;
a counter, coupled to the control clock generator, to count clock pulses of at least one of the plurality of control clocks;
a comparator, coupled to an output terminal of the RC integrator circuit, to compare a reference voltage with a voltage at the output terminal and to generate a trigger event to trigger the counter to stop counting;
a digital controller to receive the counted clock pulses and the bandwidth setting code.

6. The calibration apparatus of claim 5, wherein the trigger event is generated when the output terminal voltage is lower than the reference voltage.

7. The apparatus of claim 5, wherein the RC integrator circuit is calibrated based on a product of a clock period of the at least one of the plurality of control clocks and the bandwidth setting code, wherein the bandwidth setting code can be set to different arbitrary codes respectively corresponding to different RC time constants.

8. The calibration apparatus of claim 5, wherein the control clock generator further comprises:
a first frequency divider to generate the at least one of the plurality of control clocks of a first frequency; and
a second frequency divider to receive the at least one of the plurality of control clocks and to generate a second clock of a second frequency, the second frequency being less than the first frequency, wherein the second frequency divider provides the second clock to the comparator.

9. The calibration apparatus of claim 5, wherein the digital controller further comprises:
a subtractor circuit to perform a subtraction of a number of the counted clock pulses from the bandwidth setting code to calculate a difference; and
an adder circuit to perform an addition of the difference and the current capacitance value of the RC integrator circuit, wherein the capacitance control code is generated based on the addition.

10. The apparatus of claim 9, wherein the digital controller comprises a cut-off circuit to remove power from the control clock generator, the counter, the comparator, the capacitance code generator, and the digital controller, when the difference is zero.

11. An apparatus, comprising:
an RC integrator circuit;
a bandwidth setting controller to provide a bandwidth setting code indicating a reference bandwidth value for calibration of the RC integrator circuit;
a capacitance code generator coupled to provide feedback to the RC circuit, to adjust capacitance of the RC integrator circuit using the bandwidth setting code and a current capacitance value of the RC integrator circuit.

12. The apparatus of claim 11, wherein the feedback includes a capacitance code generated by the capacitance code generator.

13. The apparatus of claim 12, wherein the RC integrator circuit comprises a plurality of resistors and a plurality of variable capacitors, the capacitance of the RC integrator circuit being based on an equivalent capacitance of the plurality of variable capacitors at the time of the calibration.

14. The calibration apparatus of claim 13, wherein the capacitance of the RC integrator circuit is adjusted by changing the capacitance of at least one of the plurality of variable capacitors.

15. The calibration apparatus of claim 14, wherein at least one of the plurality of variable capacitors includes an array of binary-weighted capacitors functioning as a digital-to-analog converter (DAC), to set the capacitance of the at least one variable capacitor by converting the capacitance code into an analog capacitance value.

16. The calibration apparatus of claim 12 further, comprising:
a control clock generator, to generate a plurality of control clocks;
a counter, coupled to the control clock generator, to count clock pulses of at least one of the plurality of control clocks;
a comparator, coupled to an output terminal of the RC integrator circuit, to compare a reference voltage with a voltage at the output terminal and to generate a trigger event to trigger the counter to stop counting, wherein the trigger event is generated when the output terminal voltage is lower than the reference voltage;
a digital controller to receive the counted clock pulses and the bandwidth setting code.

17. The apparatus of claim 16, wherein the RC integrator circuit is calibrated based on a product of a clock period of the at least one of the plurality of control clocks and the bandwidth setting code, wherein the bandwidth setting code can be set to different arbitrary codes respectively corresponding to different RC time constants.

18. The apparatus of claim 16, wherein the digital controller further comprises:
a subtractor circuit to perform a subtraction of a number of the counted clock pulses from the bandwidth setting code to calculate a difference; and
an adder circuit to perform an addition of the difference and the current capacitance value of the RC integrator circuit, wherein the capacitance control code is generated based on the addition.

19. The apparatus of claim 18, wherein the digital controller further comprises a cut-off circuit to remove power from the control clock generator, the counter, the comparator, the capacitance code generator, and the digital controller, when the difference is zero.

20. A calibration apparatus, comprising:
an RC integrator circuit including an output terminal;
a control clock generator, to generate a plurality of control clocks;
a counter, coupled to the control clock generator, to count clock pulses of at least one or the plurality of control clocks;
a comparator, coupled to the output terminal, to compare a reference voltage with a voltage at the output terminal and to generate a trigger event to trigger the counter to stop counting;
a digital controller to receive the counted clock pulses and to generate a bandwidth setting code; and
a capacitance code generator, coupled to the RC integrator circuit, to generate a capacitance code to adjust a capacitance of the RC integrator circuit using a current capacitance value of the RC integrator circuit and the bandwidth setting code.

21. The apparatus of claim 20, wherein the calibration apparatus further comprises:
a subtractor circuit to perform a subtraction of a number of the counted clock pulses from the bandwidth setting code to calculate a difference; and
an adder circuit to perform an addition of the difference and the current capacitance value of the RC integrator circuit, wherein the capacitance control code is generated based on the addition.

22. A method of calibrating an RC integrator circuit, comprising:
receiving a bandwidth setting code indicating a reference bandwidth value for calibration of the RC integrator circuit;
calculating a current capacitance value of the RC integrator circuit; and
generating a capacitance code to adjust the current capacitance value of the RC integrator using the bandwidth setting code and the current capacitance value of the RC integrator circuit.

23. The method of claim 22, further comprising:
generating a plurality of control clocks;
counting clock pulses of at least one of the plurality of control clocks;
comparing a reference voltage with a voltage at an output terminal of the RC integrator circuit;
causing the counter to stop counting;
calculating a difference between the bandwidth setting code and a number of the counted clock pulses; and
generating the capacitance code based on an addition of the difference and the current capacitance value.

24. The method of claim 23, further comprising generating a trigger event, to cause the counter to stop counting, when the output terminal voltage is lower than the reference voltage.

25. The method of claim 22, further comprising changing the bandwidth setting code and calibrating the RC integrator circuit based on the changed bandwidth code.

26. The method of claim 22, further comprising:
performing a digital-to-analog conversion on the capacitance code; and
adjusting the current capacitance value of the RC integrator circuit based on the conversion.

27. A method of calibrating an RC integrator circuit, comprising:
generating a plurality of control clocks;
counting clock pulses of at least one of the plurality of control clocks;
comparing a reference voltage with a voltage at an output terminal of an RC integrator circuit;
causing the counter to stop counting;
calculating a difference between a bandwidth setting code and a number of the counted clock pulses; and
adjusting the capacitance of the RC integrator circuit based on the difference.

28. The method of claim 27, wherein the capacitance of the RC integrator circuit is adjusted by generating a new capacitance control code based on an addition of a current capacitance value of the RC integrator circuit and the difference.
